(19) United States
(12) Patent Application Publication
(10) Pub. No.: US 2013/0264583 A1
(43) Pub. Date: Oct. 10, 2013

(54) POWER SEMICONDUCTOR DEVICE AND METHOD FOR MANUFACTURING SAME

(71) Applicant: SUMITOMO ELECTRIC INDUSTRIES, LTD., Osaka-shi (JP)

(72) Inventor: Hideki Hayashi, Osaka-shi (JP)

(73) Assignee: SUMITOMO ELECTRIC INDUSTRIES, LTD., Osaka-shi (JP)

(21) Appl. No.: 13/780,664

(22) Filed: Feb. 28, 2013

Related U.S. Application Data
(60) Provisional application No. 61/622,211, filed on Apr. 10, 2012.

(30) Foreign Application Priority Data
Apr. 10, 2012 (JP) 2012-088932

(51) Int. Cl. H01L 29/36; H01L 29/66; H01L 29/808

(52) U.S. Cl. CPC H01L 29/36; H01L 29/8083; H01L 29/66924; H01L 29/66068
USPC 257/77; 257/263; 257/76; 438/192

(57) ABSTRACT

A first region is interposed between a drain electrode and a source electrode in a thickness direction, and has first conductivity type. The first region includes a drift layer and a channel layer. The drift layer faces the drain electrode. The channel layer is provided on the drift layer and faces the source electrode. The drift layer has an impurity concentration higher than that of the channel layer. A second region has second conductivity type different from the first conductivity type. The second region has a charge compensation portion and a gate portion. The drift layer is interposed in the charge compensation portion in an in-plane direction that crosses the thickness direction. The channel layer is interposed in the gate portion in the in-plane direction.

### BACKGROUND OF THE INVENTION

1. Field of the Invention

The present invention relates to a power semiconductor device and a method for manufacturing the power semiconductor device.

2. Description of the Background Art

Generally in a power semiconductor device, small on-resistance and large breakdown voltage are in a trade-off relation. In order to overcome this, it has been considered to use a wide band gap semiconductor such as a silicon carbide (SiC) semiconductor or a gallium nitride (GaN) based semiconductor instead of a silicon semiconductor, which has been conventionally widely used. An exemplary power semiconductor device employing such a silicon semiconductor is a MOSFET (Metal Oxide Semiconductor Field Effect Transistor). However, at present, when applying a wide band gap semiconductor to a MOSFET, the MOSFET obtained has a channel resistance significantly larger than its theoretical estimated value, thus failing to sufficiently reduce on-resistance.

In contrast, a JFET (Junction Field Effect Transistor) attains a sufficiently low on-resistance because the channel is not limited to an interface. For example, Y. Tanaka et al., “700-V 1.0-mΩ·cm²Buried Gate SiC-SIT (SiC-BGSIT)”, IEEE Electron Device Letters, Vol. 27, No. 11 (2006), pp. 908-910 discloses a static induction transistor (SIT), i.e., a junction field effect transistor (JFET). This JFET employs SiC, and is of vertical type. According to this literature, very low on-resistance is allegedly obtained.

In recent years, demands has been increased with regard to performance of a power semiconductor device. Accordingly, it has been requested to further resolve the trade-off between small on-resistance and large breakdown voltage.

### SUMMARY OF THE INVENTION

The present invention has been made to solve the foregoing problem, and has its object to further improve the trade-off between small on-resistance and large breakdown voltage in the power semiconductor device.

A power semiconductor device of the present invention includes a drain electrode, a source electrode, a first region, and a second region. The source electrode is opposite to the drain electrode in a thickness direction. The first region has first conductivity type and is interposed between the drain electrode and the source electrode in the thickness direction. The first region includes a drift layer and a channel layer. The drift layer faces the drain electrode. The channel layer is provided on the drift layer and faces the source electrode. The drift layer has an impurity concentration higher than that of the channel layer. The second region has second conductivity type different from the first conductivity type. The second region has a charge compensation portion and a gate portion. The drift layer is interposed in the charge compensation layer in an in-plane direction that crosses the thickness direction. The channel layer is interposed in the gate portion in the in-plane direction.

According to the present device, at least part of electric field in the thickness direction due to fixed charge having one of positive and negative polarities and caused by depletion of the drift layer is compensated by fixed charge having the other polarity caused by depletion of the charge compensation portion. In other words, a charge compensation structure is provided. Accordingly, the maximum value of strength of the electric field in the thickness direction is restricted. This leads to improved breakdown voltage of the power semiconductor device.

Moreover, the drift layer has an impurity concentration higher than that of the channel layer. Accordingly, on-resistance can be suppressed.

Preferably, in the thickness direction, the charge compensation portion has a size of 5 μm or more. In this way, the maximum value of the strength of the electric field in the thickness direction can be restricted more sufficiently.

Each of the drift layer and the channel layer may be made of silicon carbide. Accordingly, there can be obtained a power semiconductor device employing a wide band gap semiconductor.

Each of the drift layer and the channel layer may be made of gallium nitride. Accordingly, there can be obtained a power semiconductor device employing a wide band gap semiconductor.

Preferably, in the in-plane direction, the charge compensation portion has a first size. The drift layer interposed in the charge compensation portion has a second size.

A product of the first size and an impurity concentration of the charge compensation portion has substantially the same value as a product of the second size and the impurity concentration of the drift layer. In this way, balance is more optimized between amounts of positive and negative charges in the charge compensation structure. This leads to further improved breakdown voltage of the power semiconductor device.

A method for manufacturing a power semiconductor device in the present invention includes the following steps. A first region is formed which includes a drift layer having first conductivity type and a channel layer provided on the drift layer in a thickness direction and having the first conductivity type. The drift layer has an impurity concentration higher than that of the channel layer. A trench is formed which extends to inside of the drift layer through the channel layer. A second region is formed which has second conductivity type different from the first conductivity type and which fills the trench. The second region has a charge compensation portion and a gate portion. The drift layer is interposed in the charge compensation layer in an in-plane direction that crosses the thickness direction. The channel layer is interposed in the gate portion in the in-plane direction. A contact layer having the first conductivity type is formed as a portion of the first region on the channel layer so as to bury the second region. A drain electrode is formed on the first region so as to face the drift layer. A source electrode is formed on the first region so as to face the channel layer.

As described above, according to the present invention, the trade-off between small on-resistance and large breakdown voltage can be further improved.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a partial cross sectional view schematically showing a configuration of a power semiconductor device in one embodiment of the present invention.

FIG. 2 is a partial cross sectional view schematically showing a first step of a method for manufacturing the power semiconductor device of FIG. 1.

FIG. 3 is a partial cross sectional view schematically showing a second step of the method for manufacturing the power semiconductor device of FIG. 1.

FIG. 4 is a partial cross sectional view schematically showing a third step of the method for manufacturing the power semiconductor device of FIG. 1.

FIG. 5 is a partial cross sectional view schematically showing a fourth step of the method for manufacturing the power semiconductor device of FIG. 1.

FIG. 6 is a partial cross sectional view schematically showing a fifth step of the method for manufacturing the power semiconductor device of FIG. 1.

### DESCRIPTION OF THE PREFERRED EMBODIMENTS

The following describes an embodiment of the present invention with reference to figures. It should be noted that in the below-mentioned figures, the same or corresponding portions are given the same reference characters and are not described repeatedly.

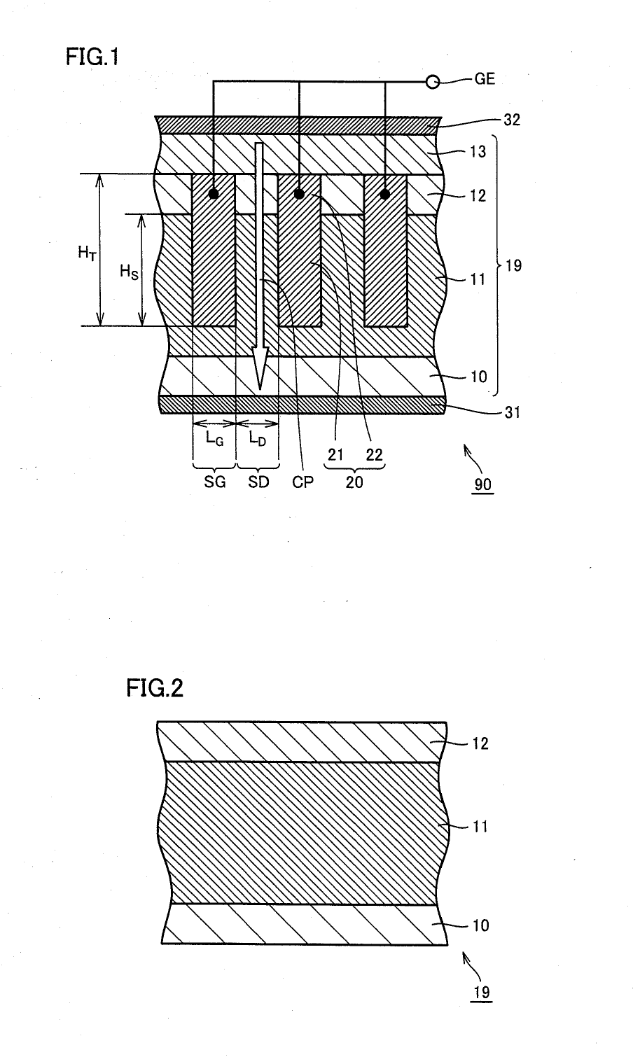

As shown in FIG. 1, a vertical type JFET 90 (power semiconductor device) of n channel type in the present embodiment includes a drain electrode 31, a source electrode 32, an n region 19 (first region), and a p region 20 (second region). Drain electrode 31 and source electrode 32 are electrodes in ohmic contact with n region 19, and are opposite to each other in the thickness direction (vertical direction in the figure).

N region 19 is interposed between drain electrode 31 and source electrode 32 in the thickness direction, and has n type conductivity. N region 19 has a single-crystal substrate 10, a drift layer 11, a channel layer 12, and a contact layer 13. Drift layer 11 faces drain electrode 31. Channel layer 12 is provided on drift layer 11 and faces source electrode 32.

Drift layer 11 has an impurity concentration higher than that of channel layer 12. Contact layer 13 has an impurity concentration higher than that of channel layer 12. Single-crystal substrate 10 has an impurity concentration higher than that of channel layer 12.

Each of drift layer 11 and channel layer 12 may be made of silicon carbide. Alternatively, each of drift layer 11 and channel layer 12 may be made of gallium nitride.

P region 20 has p type conductivity. Further, p region 20 has a charge compensation portion 21 and a gate portion 22. Drift layer 11 is interposed in charge compensation portion 21 in the in-plane direction that crosses the thickness direction. Channel layer 12 is interposed in gate portion 22 in the in-plane direction. P region 20 is connected to a gate electrode GE. Preferably, in the thickness direction, charge compensation portion 21 has a size Hₛ of 5 μm or more. Preferably, in the thickness direction, p region 20 has a size H_{T} of 10 μm or more.

In the in-plane direction, charge compensation portion 21 has a size L_{G} (first size). Further, drift layer 11 interposed in charge compensation portion 21 has L_{D} (second size).

N region 19 and p region 20 include a portion in which a structure SG having size L_{G} and a structure SD having size L_{D} are periodically repeated in the in-plane direction. Structure SG is a portion having a portion of drift layer 11 in the thickness direction, charge compensation portion 21 provided thereon, and gate portion 22 provided thereon. Structure SD is a portion having drift layer 11 and channel layer 12 provided thereon.

A product of size L_{G} and the impurity concentration of charge compensation portion 21 has substantially the same value as a product of size L_{D} and the impurity concentration of drift layer 11. Here, the expression “substantially the same value” refers to a value falling within a range of, for example, ±20%.

The following describes usage of JFET 90. Drain electrode 31 serves as a positive electrode and source electrode 32 serves as a negative electrode. JFET 90 is fed with a voltage. When the absolute value of the potential applied to gate electrode GE is less than a threshold value, carriers flow along a path CP. In other words, JFET 90 is in the ON state. When the absolute value of the potential applied to gate electrode GE exceeds the threshold value, a depletion region extends in channel layer 12, thereby interrupting path CP. Accordingly, JFET 90 is brought into the OFF state. The potential for bringing into the OFF state is, more specifically, a potential equal to or less than a particular negative threshold value in the case of n channel type as in the present embodiment, and is a potential equal to or more than a particular positive threshold value in the case of p channel type. In this way, switching operation is performed between drain electrode 31 and source electrode 32.

The following describes a method for manufacturing JFET 90.

Referring to FIG. 2, drift layer 11 is formed on single-crystal substrate 10. Next, in the thickness direction, channel layer 12 is formed on drift layer 11. In this way, n region 19 including drift layer 11 and channel layer 12 is formed. Drift layer 11 and channel layer 12 can be formed by means of, for example, a CVD (Chemical Vapor Deposition) method.

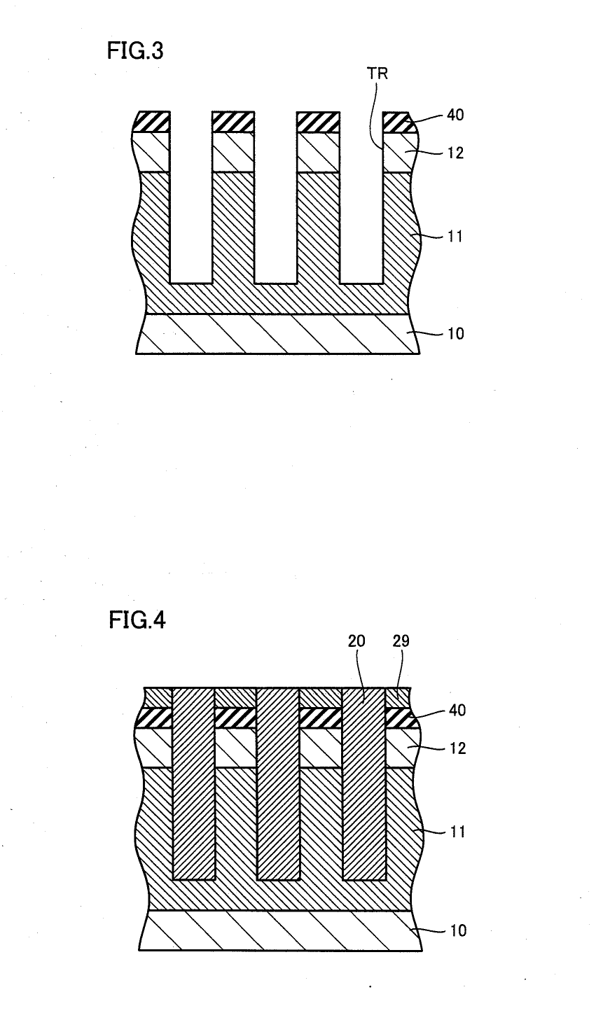

Referring to FIG. 3, on channel layer 12, a mask 40 having an opening is formed. The opening is provided in a location corresponding to p region 20 (FIG. 1). Next, anisotropic etching is performed using mask 40 to form a trench TR that extend to inside of drift layer 11 through channel layer 12.

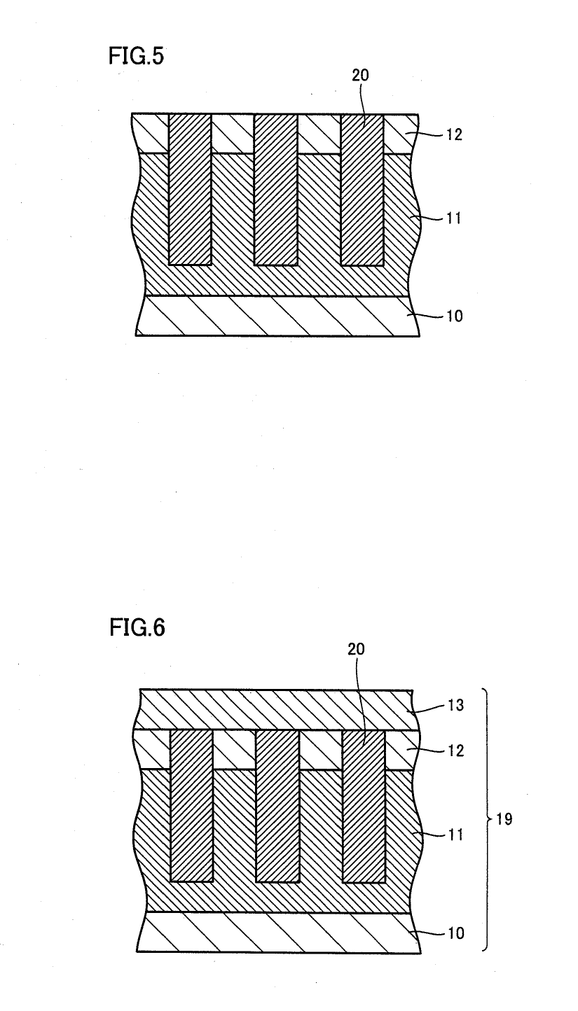

Referring to FIG. 4 mainly, a p type semiconductor is deposited. In this way, p region 20 is formed to fill trench TR. When forming p region 20, amorphous semiconductor layer 29 is formed on mask 40. Next, amorphous semiconductor layer 29, mask 40, and portions of p region 20 are removed (FIG. 5). This removal can be performed by means of, for example, CMP (Chemical Mechanical Polishing).

As shown in FIG. 6, as a portion of n region 19, contact layer 13 is formed on channel layer 12 so as to bury p region 20.

Referring to FIG. 1 again, on n region 19, drain electrode 31 is formed to face drift layer 11. Further, on n region 19, source electrode 32 is formed to face channel layer 12. In this way, JFET 90 is obtained.

According to the present embodiment, at least part of electric field in the thickness direction due to fixed charge having one of positive and negative polarities and caused by depletion of drift layer 11 is compensated by fixed charge having the other polarity and caused by depletion of charge compensation portion 21 described above. In other words, a charge compensation structure is provided. Accordingly, the maximum value of strength of the electric field in the thickness direction is restricted. This leads to improved breakdown voltage of the power semiconductor device.

Moreover, drift layer 11 has an impurity concentration higher than that of channel layer 12. Accordingly, on-resistance can be suppressed.

Preferably, in the thickness direction, charge compensation portion 21 has a size Hₛ of 5 μm or more. In this way, the maximum value of the strength of the electric field in the thickness direction can be restricted more sufficiently.

Each of drift layer 11 and channel layer 12 may be made of silicon carbide. Accordingly, there can be obtained a power semiconductor device employing a wide band gap semiconductor.

Each of drift layer 11 and channel layer 12 may be made of gallium nitride. Accordingly, there can be obtained a power semiconductor device employing a wide band gap semiconductor.

Preferably, the product of size L_{G} and the impurity concentration of charge compensation portion 21 has substantially the same value as the product of size L_{D} and the impurity concentration of drift layer 11. In this way, balance is more optimized between amounts of positive and negative charges in the charge compensation structure. This leads to further improved breakdown voltage of the power semiconductor device.

It should be noted that the description above has illustrated the configuration that has n region 19 serving as the first region of n type and p region 20 serving as the second region of p type, but a configuration in which n type and p type are replaced with each other may be employed. In this case, positive holes rather than electrons are used as carriers. In other words, the JFET becomes p channel type.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A power semiconductor device comprising:
a drain electrode;
a source electrode opposite to said drain electrode in a thickness direction;
a first region having first conductivity type and interposed between said drain electrode and said source electrode in said thickness direction, said first region including a drift layer facing said drain electrode and a channel layer provided on said drift layer and facing said source electrode, said drift layer having an impurity concentration higher than that of said channel layer; and
a second region having second conductivity type different from said first conductivity type, said second region having a charge compensation portion and a gate portion, said drift layer being interposed in said charge compensation portion in an in-plane direction that crosses said thickness direction, said channel layer being interposed in said gate portion in said in-plane direction.

2. The power semiconductor device according to claim 1, wherein in said thickness direction, said charge compensation portion has a size of 5 μm or more.

3. The power semiconductor device according to claim 1, wherein each of said drift layer and said channel layer is made of silicon carbide.

4. The power semiconductor device according to claim 1, wherein each of said drift layer and said channel layer is made of gallium nitride.

5. The power semiconductor device according to claim 1, wherein in said in-plane direction, said charge compensation portion has a first size, said drift layer interposed in said charge compensation portion has a second size, and a product of said first size and an impurity concentration of said charge compensation portion has substantially the same value as a product of said second size and the impurity concentration of said drift layer.

6. A method for manufacturing a power semiconductor device comprising the steps of:
forming a first region that includes a drift layer having first conductivity type and a channel layer provided on said drift layer in a thickness direction and having said first conductivity type, said drift layer having an impurity concentration higher than that of said channel layer;
forming a trench that extends to inside of said drift layer through said channel layer;
forming a second region that has second conductivity type different from said first conductivity type and that fills said trench, said second region having a charge compensation portion and a gate portion, said drift layer being interposed in said charge compensation portion in an in-plane direction that crosses said thickness direction, said channel layer being interposed in said gate portion in said in-plane direction;
forming a contact layer having said first conductivity type as a portion of said first region on said channel layer so as to bury said second region;
forming a drain electrode on said first region so as to face said drift layer; and
forming a source electrode on said first region so as to face said channel layer.
